(19) United States
(12) Patent Application Publication
(10) Pub. No.: US 2016/0282435 A1
(43) Pub. Date: Sep. 29, 2016

(54) MAGNETIC RESONANCE IMAGING APPARATUS

(71) Applicant: HITACHI, LTD., Tokyo (JP)

(72) Inventor: Yoshikatsu IGARASHI, Tokyo (JP)

(21) Appl. No.: 15/037,546

(22) PCT Filed: Dec. 10, 2014
(86) PCT No.: PCT/JP2014/082603

§ 371 Date: May 18, 2016

(30) Foreign Application Priority Data
Dec. 13, 2013 (JP) 2013-258536

(51) Int. Cl. G01R 33/56; G01R 33/48; G01R 33/36

(52) U.S. Cl. CPC G01R 33/5608; G01R 33/3621; G01R 33/4822

(57) ABSTRACT

In order to shorten the time to reconstruction by performing signal processing for data received by each channel at a high speed in an MRI apparatus comprising a multi-channel receive coil, a multi-core CPU that can process echo signals acquired using a plurality of channels in parallel is mounted as a signal processing device, the parallel processing of the said multi-core CPU is performed by synchronizing child tasks of the number of parallel processes in which echo signals are actually processed with a parent task that manages each child task, DMA transfer is performed between memories inside the signal processing device, and a plurality of signal processing devices and a reconstruction device that reconstructs an image from data processed in the signal processing devices are connected in a star shape via one switching device in the present invention.

### TECHNICAL FIELD

The present invention relates to a magnetic resonance imaging (MRI) technique for measuring nuclear magnetic resonance (hereinafter, referred to as “NMR”) signals from hydrogen, phosphorus, etc. in an object and imaging nuclear density distribution, relaxation time distribution, etc. and, in particular, to a technique for signal processing to be performed for echo signals acquired using a multi-channel receive coil.

### BACKGROUND ART

A method has been suggested in which load balancing of reconstruction processing and processing speed-up are achieved in an MRI apparatus comprising a plurality of receive coils (a multi-channel receive coil). For example, this can be achieved by providing signal processing devices that processes echo signals received with each channel and reconstruction devices by the number of channels and arranging them in a lattice shape in order to enable communication between the devices adjacent in horizontal and vertical directions (for example, refer to Patent Literature 1).

In the method of PTL 1, each channel data processed by each signal processing device is transferred to the reconstruction devices via a dedicated communication bus and is converted into image data by the two-dimensional Fourier transform here. The image data of all the channels converted by each reconstruction device is collected in a synthesizer provided separately from the signal processing devices and the reconstruction devices and is synthesized in order to output a final image.

### CITATION LIST

### Patent Literature

PTL 1: Japanese Unexamined Patent Publication No. 2006-218285

### SUMMARY OF INVENTION

### Technical Problem

In the method described in PTL 1, each signal processing device is provided with a hardware on which an interface for receiving single-channel echo signals mounted. Therefore, in response to channel multiplication, the signal processing devices need to be provided by the number of channels, which increases a hardware size as well as costs. Also, because transfer requests of processed data are generated simultaneously from each signal processing device, this cause an increase in the transfer data amount, and the transfer throughput is consequently reduced.

Also, a conventional signal processing device performs various correction processes for received echo signals before signal processing in order to improve image quality. However, a contrivance of accelerating an internal processing speed is not made in the conventional signal processing, and it takes a long processing time. Therefore, when the correction processes are further added, it is possible that the time to process them exceeds time of repetition (TR). This eventually results in prolonging reconstruction processing time.

The present invention was made in consideration of the above problem, and high-speed signal processing is performed for receive data of each channel in an MRI apparatus comprising a multi-channel receive coil, which shortens time for reconstruction.

### Solution to Problem

In the present invention, as a signal processing device, a multi-core CPU that can process echo signals acquired using a plurality of channels in parallel is mounted. The parallel processing of the said multiple CPU is performed by synchronizing child tasks of the number of parallel processes in which echo signals are actually processed with a parent task that manages each child task. Inside the signal processing device, DMA transfer is performed between memories, and a plurality of signal processing devices and a reconstruction device that reconstructs an image from data processed in the signal processing devices are connected in a star shape via one switching device.

### Advantageous Effects of Invention

According to the present invention, high-speed signal processing is performed for receive data of each channel in an MRI apparatus comprising a multi-channel receive coil, which can shorten time for reconstruction.

### BRIEF DESCRIPTION OF DRAWINGS

FIG. 1 is a block diagram of an MRI apparatus of a first embodiment.

FIG. 2 is a block diagram of a control processing system of the first embodiment.

FIG. 3 is a block diagram of a DRF calculator of the first embodiment.

FIG. 4 is an explanatory diagram for explaining synchronization processing of a parent task and child tasks of the first embodiment.

FIG. 5 is an explanatory diagram for explaining an assignment example of the first embodiment.

FIG. 6 is an explanatory diagram for explaining a relationship between resampling filters and echo signal data to be applied in the first embodiment.

FIGS. 6(a), 6(b), and 6(c) are explanatory diagrams of a first point after thinning out; a second point after thinning out; and an n-th point after thinning out respectively.

FIG. 7(a) is a flow chart of pre-processing for the parent task of the first embodiment, and FIG. 7(b) is a flow chart of pre-processing for the child tasks of the first embodiment.

FIG. 8 is a flow chart of processes while measuring the parent task of the first embodiment.

FIG. 9 is a flow chart of processes while measuring the child tasks of the first embodiment.

FIG. 10 is an explanatory diagram for explaining signal processing within one TR of the first embodiment.

FIG. 11 is a block diagram of a conventional image processing device.

FIG. 12 is an explanatory diagram for explaining conventional signal processing within one TR.

FIG. 13 is an explanatory diagram for explaining processes within one shot when applying an EPI sequence in the first embodiment.

FIG. 14 is an explanatory diagram for explaining synchronization processing of a parent task and child tasks of a second embodiment.

FIG. 15 is a flow chart of processes while measuring the parent task of the second embodiment.

FIG. 16 is a flow chart of processes while measuring the child tasks of the second embodiment.

FIG. 17 is an explanatory diagram for explaining signal processing when acquiring navigator echoes of the second embodiment.

FIG. 18(a) is an explanatory diagram for explaining conventional channel assignment, and FIG. 18(b) is an explanatory diagram for explaining a variation of channel assignment of the present invention.

FIG. 19 is a block diagram of a variation of the control processing system of the present invention.

### DESCRIPTION OF EMBODIMENTS

An MRI apparatus relating to the present embodiment is characterized by comprising a receive coil having a plurality of channels and an image processing device that processes signals received by the receive coil to obtain an image, that the image processing device comprises one or more signal processing devices; one switching device; and an image reconstruction device connected to each of the one or more signal processing devices via the one switching device, that each of the signal processing devices comprises a multi-core CPU provided with a plurality of logic cores; performs signal processes in parallel for signals received with two or more previously assigned channels from among the plurality of channels by the said multi-core CPU; and generates processed data for each channel, and that the image reconstruction device reconstructs an image from the processed data for each channel.

Also, each of one or more signal processing devices is characterized by comprising a task generation function, that the task generation function generates one parent task and a plurality of child tasks to be simultaneously executed under the said parent task, and that each child task is assigned to one logic core to perform the signal processing.

Also, the parent task and each of the child tasks are characterized by performing pre-processing for generating data to be used for the signal processing prior to the said signal processing. Also, the signal processing is characterized by including resampling processing that thins out the signals, that the parent task generates a plurality of filters to be used for the resampling processing as data to be used for the signal processing in the pre-processing, and that each child task determines filters whose phases correspond to each other from among the plurality of generated filters for each sampling point to be used for the resampling processing as data to be used for the signal processing in the pre-processing to generate a table in which the said sampling point corresponds to the said filters.

Also, the signals received by the receive coil are characterized by being navigator echoes to detect displacement of a detection target site and that the signal processing devices calculate the displacement of a detection target site using the navigator echoes.

Also, when the number of channels to be assigned to the one signal processing device is equal to or more than the number of logic cores of the said signal processing device, the task generation function is characterized by generating the child tasks by the number of logic cores, that the parent task assigns the channels to each child task according to the predetermined assignment, that the child tasks perform the signal processing for signals acquired by the assigned channels to obtain the processed data, and that the parent task collectively transmits processed data of all the assigned channels to the image reconstruction device.

Also, a measurement control device is further provided, and the measurement control device is characterized by almost equally assigning the plurality of channels to each of the signal processing devices.

Also, a measurement control device is further provided, the two or more image reconstruction devices are connected via the switching device, and the measurement control device is characterized by determining the image reconstruction device that processes each of the processed data so that processing loads of the respective image reconstruction devices are approximately equal.

Also, each of the signal processing devices is characterized by comprising a receive memory that temporally stores the received signals and a main memory that stores the received signals when the signal processing is performed and that the received signals are DMA-transferred to the main memory from the receive memory.

Also, the receive memory is characterized by being a double-sided switching system memory that can store and read out the received signals in parallel.

Also, each of the signal processing devices is characterized by comprising a receive interface that can receive a plurality of signals in parallel.

### First Embodiment

Hereinafter, embodiments of the present invention will be described using the attached drawings. Additionally, in all the drawings to describe the embodiments of the present invention, unless otherwise stated, the same reference signs are used for the same functions, and the repeated explanations are omitted.

<Apparatus Configuration>

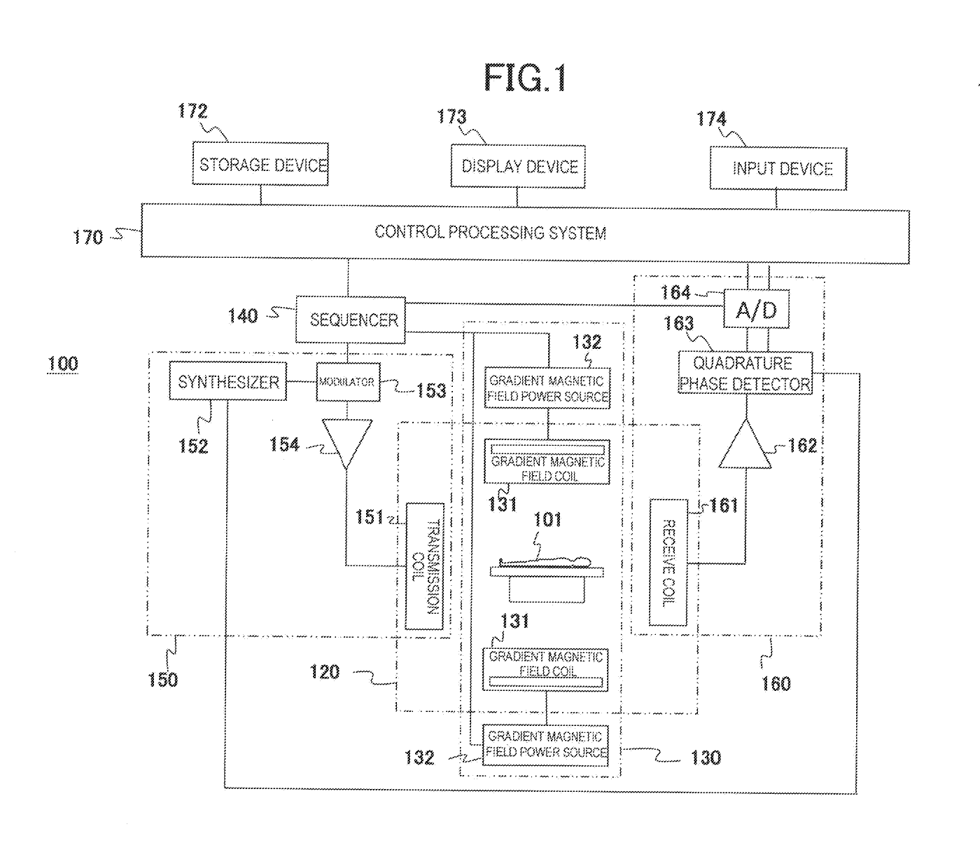

First, an overview of an example of the MRI apparatus relating to the present invention will be described based on FIG. 1. FIG. 1 is a block diagram showing an overall configuration of an embodiment of the MRI apparatus relating to the present invention.

An MRI apparatus 100 of the present embodiment obtains tomographic images of an object using an NMR phenomenon and comprises a static magnetic field generating system 120; a gradient magnetic field generating system 130; a high-frequency magnetic field generating system (hereinafter, referred to as a transmission system) 150; a high-frequency magnetic field detecting system (hereinafter, referred to as a reception system) 160; a control processing system 170; and a sequencer 140.

The static magnetic field generating system 120 generates a uniform static magnetic field in a space around an object 101 in a direction orthogonal to the body axis in the case of a vertical magnetic field type or in the body axis direction in the case of a horizontal magnetic field type and comprises a permanent magnet, normal conducting, or superconducting type of static magnetic field generating source to be disposed around the object 101.

The gradient magnetic field generating system 130 comprises gradient magnetic field coils 131 wound in the three-axis directions of X, Y, and Z that are a coordinate system (apparatus coordinate system) of the MRI apparatus 100 and gradient magnetic field power sources 132 that drive the respective gradient magnetic field coils and applies gradient magnetic fields Gx, Gy, and Gz in the three-axis directions of X, Y, and Z by driving the gradient magnetic field power sources 132 of the respective gradient magnetic field coils 131 according to a command from a sequencer 140 to be described later.

A slice-direction gradient magnetic field pulse is applied in a direction orthogonal to a slice plane (imaging cross section) during imaging in order to set the slice plane for the object 101, and a phase-encoding-direction gradient magnetic field pulse and a frequency-encoding-direction gradient magnetic field pulse are applied in the two other directions orthogonal to the slice plane and each other in order to encode positional information in each direction for echo signals.

The transmission system 150 irradiates a high-frequency magnetic field pulse (hereinafter, referred to as “RF pulse”) to the object 101 in order to cause nuclear magnetic resonance in nuclear spins of atoms constituting biological tissues of the object 101 and comprises a high-frequency oscillator (synthesizer) 152, a modulator 153, a high-frequency amplifier 154, and a high-frequency coil (transmission coil) 151 on the transmission side. The high-frequency oscillator 152 generates and outputs an RF pulse. The modulator 153 amplitude-modulates an output RF pulse at a timing commanded from the sequencer 140, and the high-frequency amplifier 154 amplifies the amplitude-modulated RF pulse to supply to the transmission coil 151 disposed in the vicinity of the object 101. The transmission coil 151 irradiates the supplied RF pulse to the object 101.

The reception system 160 detects nuclear magnetic resonance signals (NMR signals and echo signals) emitted by nuclear magnetic resonance of nuclear spins of atoms constituting biological tissues of the object 101 and comprises a high-frequency coil (receive coil) 161 on the reception side, a signal amplifier 162, a quadrature phase detector 163, and an A/D converter 164. The receive coil 161 is disposed in the vicinity of the object 101 and detects response echo signals of the object 101 induced by an electromagnetic wave irradiated from the transmission coil 151. The detected echo signals are amplified by the signal amplifier 162, are divided into orthogonal two-system signals by the quadrature phase detector 163 at a timing commanded from the sequencer 140, and then are respectively converted into a digital amount by the A/D converter 164 before being transmitted to the control processing system 170.

In the present embodiment, the receive coil 161 is a multi-channel coil composed of a plurality of sub-coils. Each sub-coil (channel) is provided with the signal amplifier 162, the quadrature phase detector 163, and the A/D converter 164, and echo signals converted into a digital amount for each sub-coil (channel) are transmitted to the control processing system 170.

The sequencer 140 applies an RF pulse and a gradient magnetic field pulse according to a command from the control processing system 170. Specifically, according to the command from the control processing system 170, various commands required to collect data of tomographic images of the object 101 are transmitted to the transmission system 150, the gradient magnetic field generating system 130, and the reception system 160.

The control processing system 170 controls the entire MRI apparatus 100, performs calculation such as various data processing, displays and stores the processing results, and the like. The control processing system 170 is connected to a storage device 172, a display device 173, and an input device 174. The storage device 172 comprises internal storage devices such as a hard disk and external storage devices such as an external hard disk, an optical disk, and a magnetic disk. The display device 173 is a display device such as a CRT display and a liquid crystal display. The input device 174 is an interface to input various control information of the MRI apparatus 100 and control information of processes to be performed by the control processing system 170 and comprises, for example, a trackball or a mouse and a keyboard. The input device 174 is disposed in the vicinity of the display device 173. An operator interactively inputs commands and data required for various processes of the MRI apparatus 100 through the input device 174 while checking the display device 173.

The control processing system 170 realizes each process of the control processing system 170 such as operation control of the MRI apparatus 100 and various data processes by executing a program previously stored in the storage device 172 according to a command input by an operator. A command to the above sequencer 140 is made according to a pulse sequence previously stored in a storage device. Also, when data from the reception system 160 is input to the control processing system 170, the control processing system 170 executes signal processing; image reconstruction processing; and the like, displays resulting tomographic images of the object 101 on the display device 173, and then stores them in the storage device 172.

The transmission coil 151 and the gradient magnetic field coils 131 are installed opposite to the object 101 in the case of a vertical magnetic field type or so as to surround the object 101 in the case of a horizontal magnetic field type in a static magnetic field space of the static magnetic field generating system 120 where the object 120 is inserted. Also, the receive coil 161 is installed opposite to or so as to surround the object 101.

Currently, a clinically prevalent imaging target nuclide of an MRI apparatus is hydrogen nucleus (proton) that is a main component of the object 101. The MRI apparatus 100 two- or three-dimensionally images the shapes or functions of the head, abdomen, limbs, and the like by visualizing information about spatial distribution of proton density and spatial distribution of relaxation time in an exited state.

<Functional Configuration of Control Processing System>

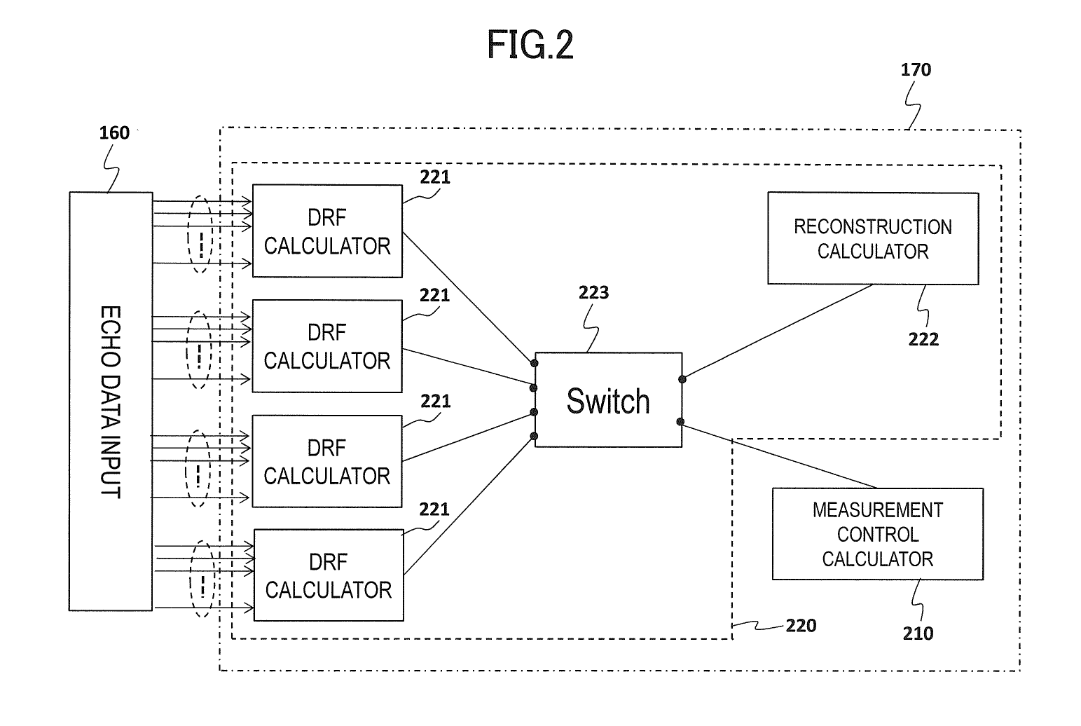

In the present embodiment, the control processing system 170 processes multi-channel data received by the reception system 160 in parallel at a high speed. In order to achieve this, the control processing system 170 of the present embodiment comprises a measurement control device (measurement control calculator) 210 that controls and measures each part and an image processing device 220 that processes signals received by the receive coil 161 having a plurality of channels to obtain an image as shown in FIG. 2.

Also, the image processing device 220 of the present embodiment comprises one or more signal processing devices (DRF calculators) 221, one switching device 223, and an image reconstruction device (reconstruction calculator) 222 to be connected to each of the one or more signal processing devices 221 via the one switching device 223. Additionally, FIG. 2 shows a case of having the four DRF calculators 221 as an example.

<Connection>

As shown in FIG. 2, each of the DRF calculators 221, the reconstruction calculator 222, and the measurement control calculator 210 are connected via one switching device (switch) 223 in a star-shaped topology. A switching hub or the like is used for the switching device 223.

<Measurement Control Calculator>

In the present embodiment, the measurement control calculator 210 determines a channel where each of the DRF calculators 221 performs processing according to determination of the total number of channels. The total number of channels is determined by determining the receive coil 161 to be used for imaging. Specifically, the measurement control calculator 210 determines a receive line (transmission path) to be input by each of the DRF calculators 221. Additionally, hereinafter, determining the receive line to be input by each of the DRF calculators 221 is referred to as assigning channels (to be processed). The measurement control calculator 210 comprises a CPU and a memory, and the functions of the measurement control calculator 210 are realized by executing a program previously included in the CPU of the measurement control calculator 210.

<Reconstruction Calculator>

The reconstruction calculator 222 reconstructs an image from resampled data (processed data) to be transmitted from each of the DRF calculators 221 for each channel. In order to reconstruct an image of each channel, a two-dimensional Fourier transform is performed for the processed data of each channel, and then images of all the channels are synthesized. The images generated by the reconstruction calculator 222 are displayed on the display device 173. The reconstruction calculator 222 comprises a CPU and a memory, and the functions of the reconstruction calculator 222 are realized by executing a program previously included in the CPU of the reconstruction calculator 222.

<DRF Calculator>

Each of the DRF calculators 221 comprises a multi-core CPU provided with a plurality of logic cores and performs parallel processing for signals (data converted into a digital amount) received with two or more channels assigned previously from among a plurality of channels of the receive coil 161 using the said multi-core CPU in order to generate data processed for each channel. The assignment is made by the measurement control calculator 210 as described above. In the present embodiment, one or more channels are assigned to one of the DRF calculators.

The number of the DRF calculators 221 is determined according to the number of channels that can be processed by the DRF calculators 221 and the maximum number of channels of the MRI apparatus 100. For example, the system configuration of the MRI apparatus 100 includes 32 channels. In a case where one of the DRF calculators 221 can process echo signals of eight channels, the four DRF calculators 221 are disposed.

Additionally, according to the number of channels required by the system of the MRI apparatus, the number of transmission paths can be adjusted by adjusting the number of the DRF calculators 221. The transmission paths of echo signals according to the number of channels (sub-coils) are bound by a plurality of channels and connected to a dedicated interface of the DRF calculator 221.

<DRF Calculator Configuration>

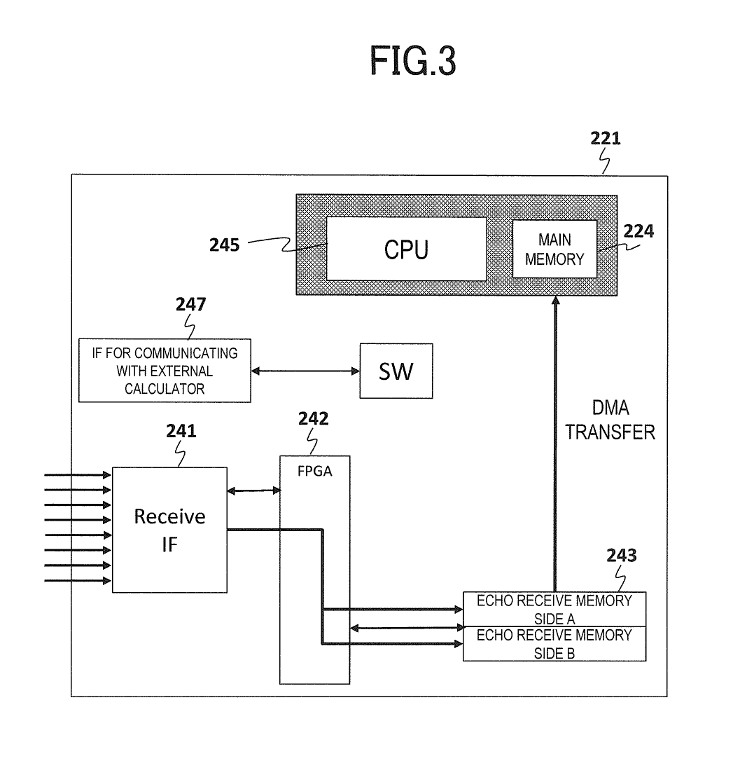

As shown in FIG. 3, each of the DRF calculators 221 comprises a receive interface (Receive I/F) 241, an FPGA (Field Programmable Gate Array) 242, an echo receive memory 243, a main memory 244, a CPU 245, a switch (SW) 246, and an external communication interface (external calculator communication I/F) 247.

The receive I/F 241 is an interface dedicated to receive echo signals. In the present embodiment, the interface is configured so as to be able to receive echo signals of a plurality of channels in parallel.

The echo receive memory 243 is a memory to temporarily store the echo signals received by the receive I/F 241 and has storage areas divided for each channel. A size of the echo receive memory is calculated from a maximum AD time and an AD sampling rate that were estimated in all imaging sequences.

Also, in the present embodiment, a double-sided switching system memory that can receive and read out signals in parallel is used for the echo receive memory 243. For example, used is a two-sided (sides A and B) bank-type memory that can perform calculation processing and reception processing in parallel. This can prevent data from being overwritten and being lost in a case where a total time including echo reception and the subsequent DMA transfer to the main memory exceeds TR.

The FPGA controls memory transfer in the DRF calculators 221. For example, the FPGA controls storage of echo signals received by the receive I/F 241 in the echo receive memory 243. Also, the FPGA functions as a DMA controller and performs DMA transfer from the echo receive memory 243 to the main memory 244.

The echo receive memory 243 is used as a temporary buffer and transfers data to the main memory 244 accessible from the CPU 245 at a high speed when signal processing such as resampling processing is performed. In the present embodiment, the transfer between the echo receive memory 243 and the main memory 244 is executed in a DMA mode. This reduces a load generated to the CPU 245 due to the data transfer.

The CPU 245 performs signal processing for data stored in the main memory 244. The CPU 245 of the present embodiment is a multi-core CPU comprising a plurality of logic cores as described above. Then, parallel processing is realized by processing signals received by two or more channels with each logic core.

Also, the CPU 245 realizes a task generation function by executing a previously stored program in the present embodiment. The task generation function generates one parent task and a plurality of child tasks to be executed simultaneously under the said parent task. Parallel calculation processing of echo signals from a plurality of channels is realized by the child tasks.

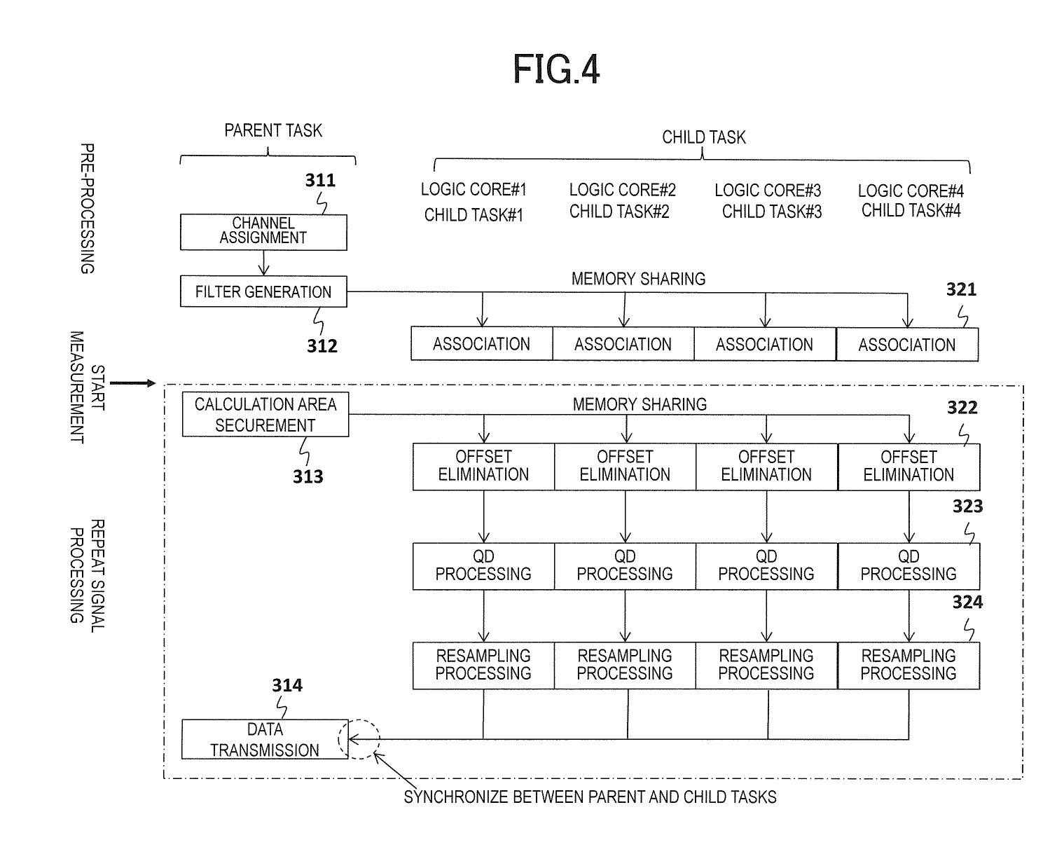

As shown in FIG. 4, the child tasks are generated by the number of logic cores. For example, in a case where the specification of the CPU 245 mounted on the DRF calculator 221 shows two physical cores and four logic cores, four child tasks are generated. Then, each child task is assigned one-to-one to each logic core simultaneously with the generation. In case of automatic scheduling in an OS, because it is unknown which logic core is assigned to each of the generated child tasks, it is difficult to identify a channel of data in which an error has occurred when a failure or the like occurs during calculation. In order to prevent this, the assignment is performed. By performing the assignment, calculated data is easily managed in software.

Additionally, when the number of channels assigned to the said DRF calculator 221 is less than that of the logic cores, the child tasks are generated by the number of channels.

Prior to signal processing, parent and child tasks performs pre-processing for generating various data to be used for the signal processing before starting measurement. Also, during the measurement, a plurality of the child tasks use the generated data to perform the signal processes in parallel according to a command from the parent task.

<Processes of Parent Task>

A parent task performs pre-processing before measurement and controls and manages a plurality of generated child tasks during the measurement.

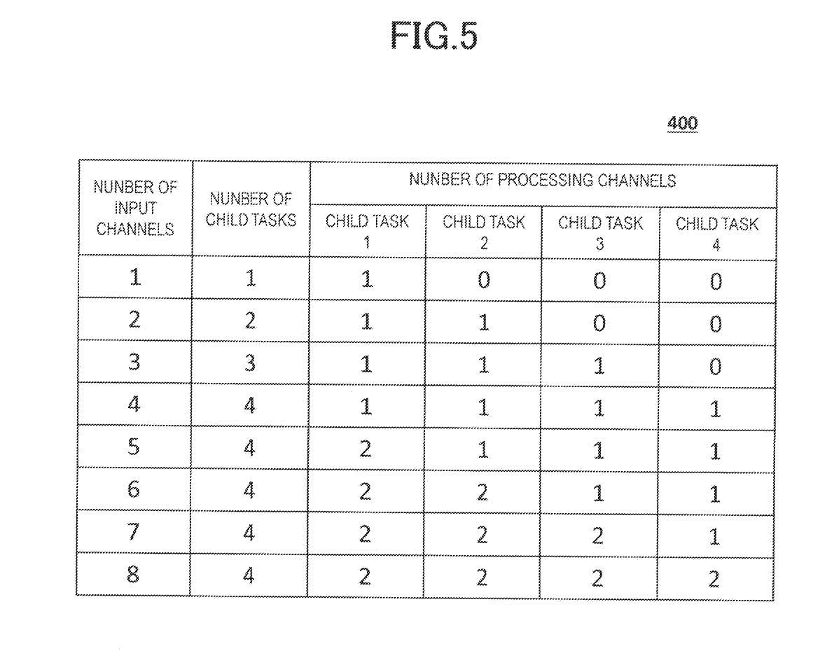

As the pre-processing, the parent task determines the number of channels to be processed by the DRF calculator 221 and performs channel assignment 311 that assigns channels to each child task. That is, when the total number of channels is determined after a receive coil to be used for imaging is selected, the parent task obtains information about a receive line to be input in the DRF calculator 221 from the measurement control calculator 210 before measurement processing and calculates the total number of channels that executes calculation processing of received signals based on the information. Then, the channels are assigned to each child task. As shown in FIG. 5, for example, the parent task determines the assignment so that loads do not concentrate on a certain child task by calculation for each measurement.

Also, the parent task generates (filter generation 312) various data (for example, filters and the like) required in order for the child tasks to perform signal processing calculation as the pre-processing and stores the data in a shared memory area of the main memory 244.

Additionally, hereinafter, in the present embodiment, the data is stored in the predetermined shared memory area, and a head address in the stored memory area is stored in a pointer of global variables for child tasks accessing the said memory area. This process is referred to as memory sharing. Therefore, the parent task converts generated various data (filters) into a shared memory. Hence, all the child tasks can refer to the generated data.

Here, the details of the various data generated by the parent task in the pre-processing are described. The various data generated in the pre-processing is various filters to be used by the child tasks in signal processing such as QD detection processing (hereinafter, referred to as QD processing) and resampling processing.

The QD processing is to separate echo signals for which AD conversion was performed into components of real and imaginary parts. Specifically, as the QD processing, calculation is performed according to the following formulas (1-1) and (1-2).

real(t)=sig(t)×cos(θ) (1-1)

imag(t)=sig(t)×sin(θ) (1-2)

Additionally, “real(t)” and “imag(t)” indicates real and imaginary part data of echo signals respectively; “sig(t)” indicates the echo signals; “t” indicates time; and “θ” indicates a phase value to be calculated from an AD sampling rate.

The resampling processing is to thin out signals to a band width of imaging conditions for the real and imaginary part data after the QD processing. In the present embodiment, sampling processing is performed using low-pass filters. In the present embodiment, used as the resampling filters are FIR filters H(n) in which an infinite impulse response h(n) is multiplied by a Kaiser window function w(n). The calculation formula of the FIR filters H(n) is as the following formula (2).

$$H ( n ) = h ( n ) w ( n ) \\ w ( n ) = s \frac{{I}_{0} \{ α \sqrt{1 - {( 2 n / N - 1 )}^{2}} \}}{{I}_{0} ( α )} , \\ if \vert n \vert \leq ( N - 1 ) / 2 \qquad ( 2 )$$

Here, “s” indicates a cutoff frequency; “I₀” indicates a class 1 zero-order modified Bessel function; “α” indicates an arbitrary real number that determines a window shape; and “N” indicates a filter length.

A parent task generates a table of sin(θ) and cos(θ) to be used in QD processing and generates FIR filters H(n) to be used in resampling processing for each predetermined phase to form the filter as a shared memory. That is, a plurality of different filters are generated in the present embodiment.

Next, description will be made about processing to be performed by the parent task during measurement, i.e. processing during measurement.

The parent task secures calculation memories that child tasks use by the number of the child tasks during the measurement, i.e. when echo signal reception starts (calculation area securement 313). The secured memory area becomes a shared memory. Then, this notification is forwarded to each child task.

Furthermore, the parent task transmits processed data stored in the shared memory area (data transmission 314) to the reconstruction calculator 222 after being notified of completion of the processing during measurement from the child tasks.

<Processes of Child Tasks>

Child tasks perform FIR filter association 321 as pre-processing. Also, the child tasks perform signal processing for each received echo signal after receiving the start notification from the parent task during measurement.

As association processing of FIR filters, the child tasks determine filters having corresponding phases from among filters generated for each phase in each sampling point in the frequency encoding direction and generate a table in which the sampling points and the filters are associated. At this point, the number of applied FIR filters and an address of the data starting point in the memory area where data after QD processing was stored are further stored for each sampling point in the said table.

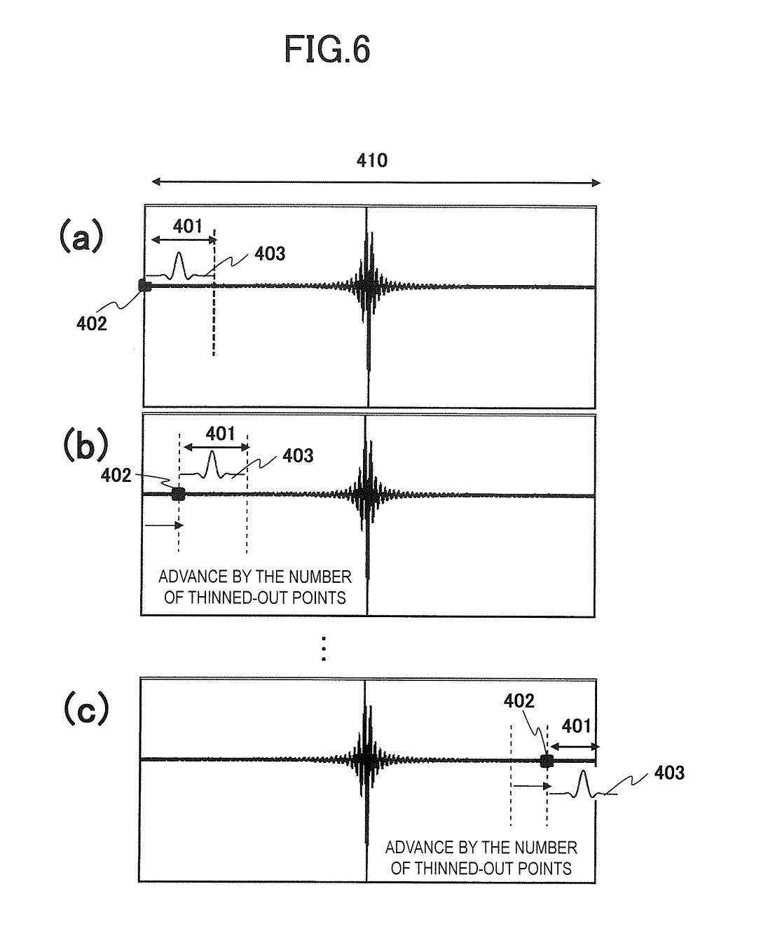

FIG. 6 is an explanatory diagram for explaining resampling processing using the above information. FIG. 6(a) shows a first point after thinning out, FIG. 6(b) shows a second point after thinning out, and FIG. 6(c) shows a N-th point after thinning out.

The number of applications 401 of FIR filters is basically the number of FIR filters. However, when offsets 404 are performed by the number of thinned-out points and, for example, in a case where FIR filters 403 to be applied exceed the number of AD points of echo signals at an end or the like, the number of the applied points is reduced and adjusted.

A data starting point address 402 is information of data to which the FIR filters 403 are applied. The data starting point address 402 is calculated as an address of the starting point where the FIR filters 403 are applied using addresses in an area of each child task secured by the parent task after QD processing.

The filters with the optimal phases 403 are applied at each starting point. Here, the filters with the optimal phases 403 are selected in order to apply the resampling processing results to a resampling interval (=an inverse number of the band width) set as an imaging condition. The type of FIR filters to be generated changes depending on an AD sampling frequency and a quantizing unit of the resampling interval.

Next, processing to be performed by chaild tasks during measurement will be described. The child tasks perform offset removal 322, QD processing 323, and resampling processing 324 after being notified of the processing start from the parent task.

Additionally, the offset removal 322 is processing to reduce bright spot generation. According to the following formula (3), an offset component is subtracted from echo signals before the QD processing 323 and the resampling processing 324. Additionally, the offset component is an average value of each echo signal.

sig′(t)=sig(t)−offset (3)

The QD processing 323 and the resampling processing 324 are as described above.

The child tasks form the acquired processed data as a shared memory after these processes and transmit processing end notifications to the parent task. The notification is performed after processing one echo data of all the assigned channels. Additionally, as shown in FIG. 4, each child task executes pre-processing and processing during measurement in parallel.

As described above, the parent task receives the end notifications of all the child tasks, and then transmits the processed data of all the channels to the reconstruction calculator 222 all at once. Subsequently, these processes will be repeated until the measurement ends.

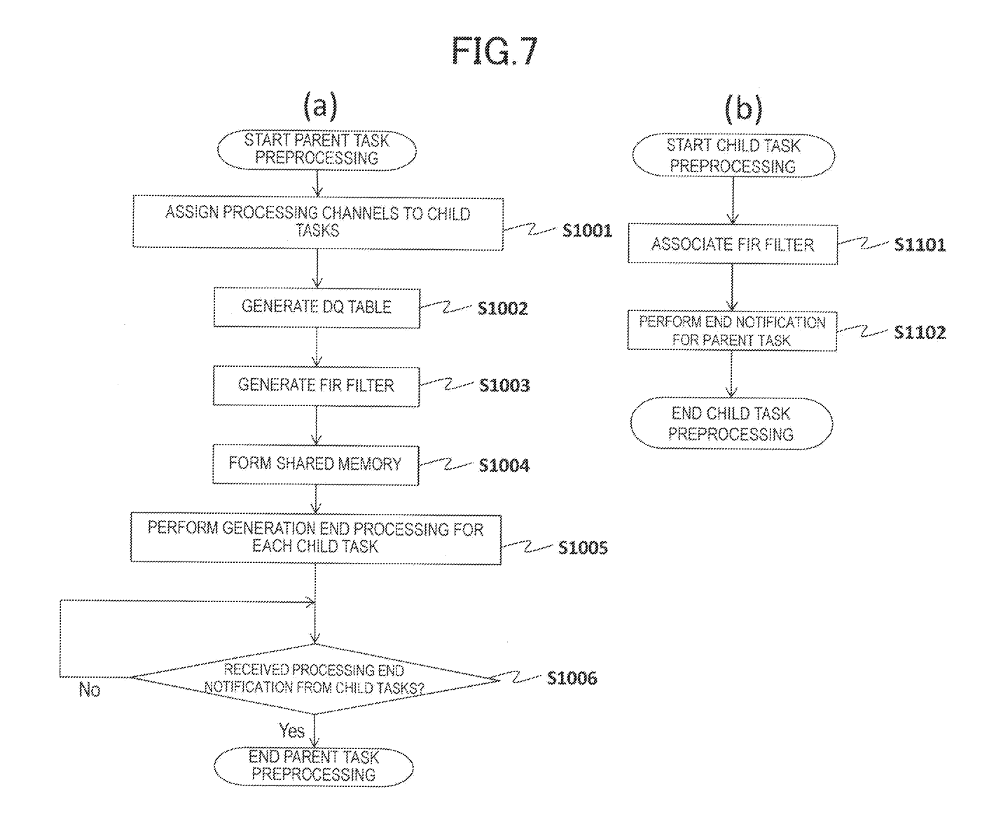

The described flow of the signal processing by the parent task and the child tasks will be described using flow charts. FIG. 7(a) is a processing flow for pre-processing of the parent task. FIG. 7(b) is a processing flow for pre-processing of the child tasks of the first embodiment. The pre-processing of the parent task starts at a timing when imaging conditions such as imaging parameters are determined.

The parent task first identifies the number of reception channels and assigns the processing channels to each child task based on the identification (Step S1001). Then, using the above method, a QD table is generated (Step S1002), and then FIR filters are generated (Step S1003). Here, the parent task forms the generated QD table and the generated FIR filters as a shared memory (Step S1004).

When forming the shared memory ends, generation end is notified to each child task (Step S1005), and processing end notifications from the child tasks are waited.

When the processing end notifications are received from the child tasks (Step S1006), the parent task ends pre-processing of the parent task.

On the other hand, when each child task receives a notification of FIR filter generation end from the parent task, child task pre-processing starts.

Each child task performs FIR filter association using the above method (Step S1101), the processing end is notified to the parent task (Step S1102), and then the child task processing ends.

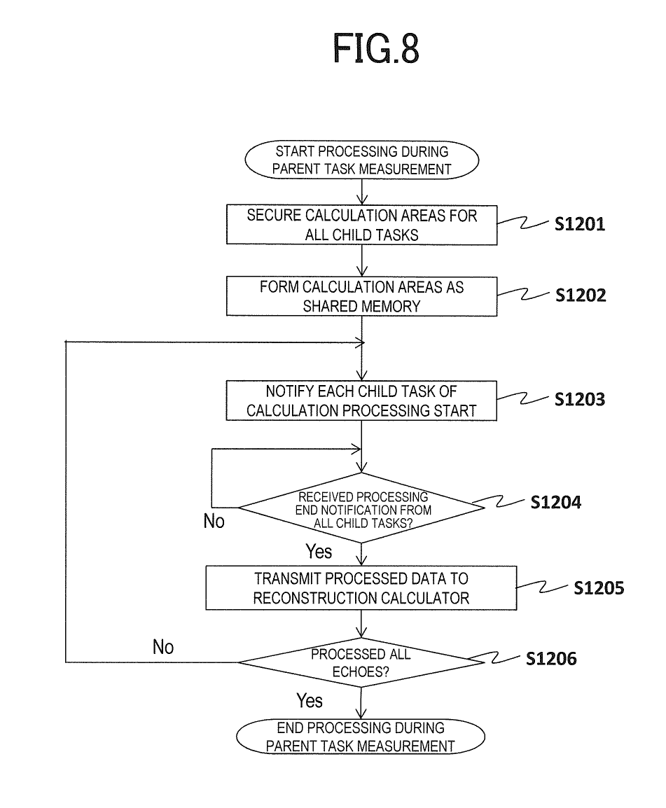

Next, a flow of processing during measurement by the parent and child tasks will be described. FIG. 8 is the processing flow of the processing during measurement by the parent task in the present embodiment. When echo signals are received from a receive line after the measurement starts, the CPU 245 is interrupted. Triggered by this, a DMA controller performs DMA transfer from the echo receive memory 243 to the main memory 244 by the number of reception channels. After this, the parent task starts processing during measurement.

The parent task secures calculation areas of all the child tasks (Step S1201). Then, the secured calculation areas are formed as a shared memory (Step S1202). Additionally, the echo signals DMA-transferred to the main memory 244 are formed as a shared memory after the parent task secures the calculation areas of all the child tasks. After this, each child task is directed so as to start child task processing during measurement (Step S1203). Then, processing end notifications from the child tasks are waited.

The parent task receives the processing end notifications from all the child tasks (Step S1204), and then transmits processed data to the reconstruction calculator 222 (Step S1205).

The parent task repeats processes from Step S1203 to Step S1205 for all processing echoes in one measurement (Step S1206) and ends the processing.

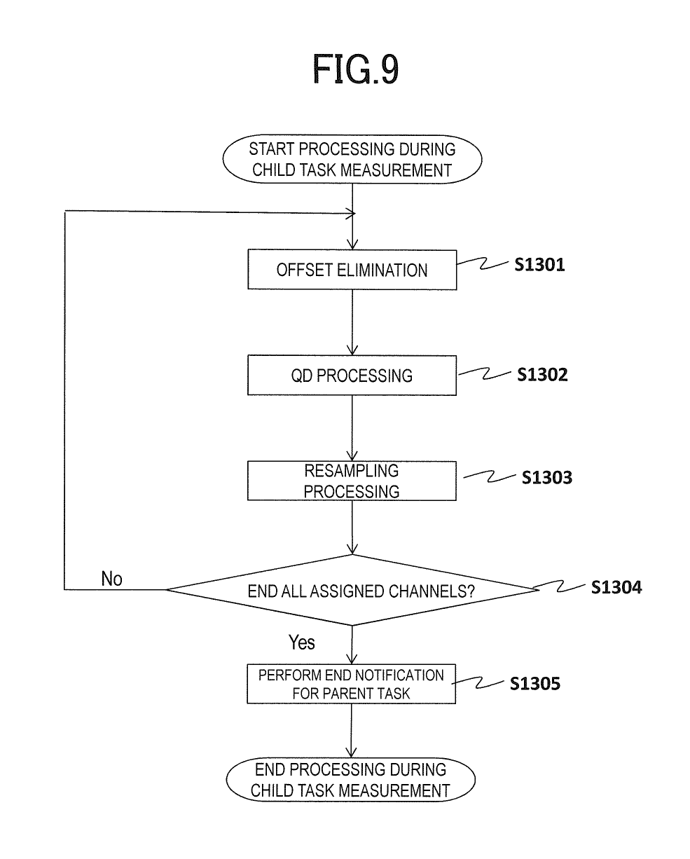

Described next is a processing flow while measuring one child task that is performed at a timing when a start notification is received from the parent task. FIG. 9 is a processing flow chart of processes while measuring the child tasks.

The child tasks first perform offset elimination processing for echo signals for the first channel (Step S1301). After this, QD processing is performed by referring to a QD table (Step S1302), and then resampling processing is performed according to the association using FIR filters (Step S1303). The processed echo signals are stored as processed data in a shared memory area.

The child tasks perform processes from Step S1301 to Step S1303 for echo signals of all the assigned channels (Step S1304). Then, after the echo signals of all the channels are processed, a processing end notification is transmitted to the parent task (Step S1305), and the child task processing during measurement ends.

As shown in FIG. 4, each child task performs the processes shown in FIG. 9 in parallel. Then, the parent and child tasks synchronize pre-processing and processing during measurement with each other before the execution.

<Comparison to Conventional Processing>

Here, flows of processing within one TR are compared between signal processing of the present embodiment and that of a conventional signal processing device.

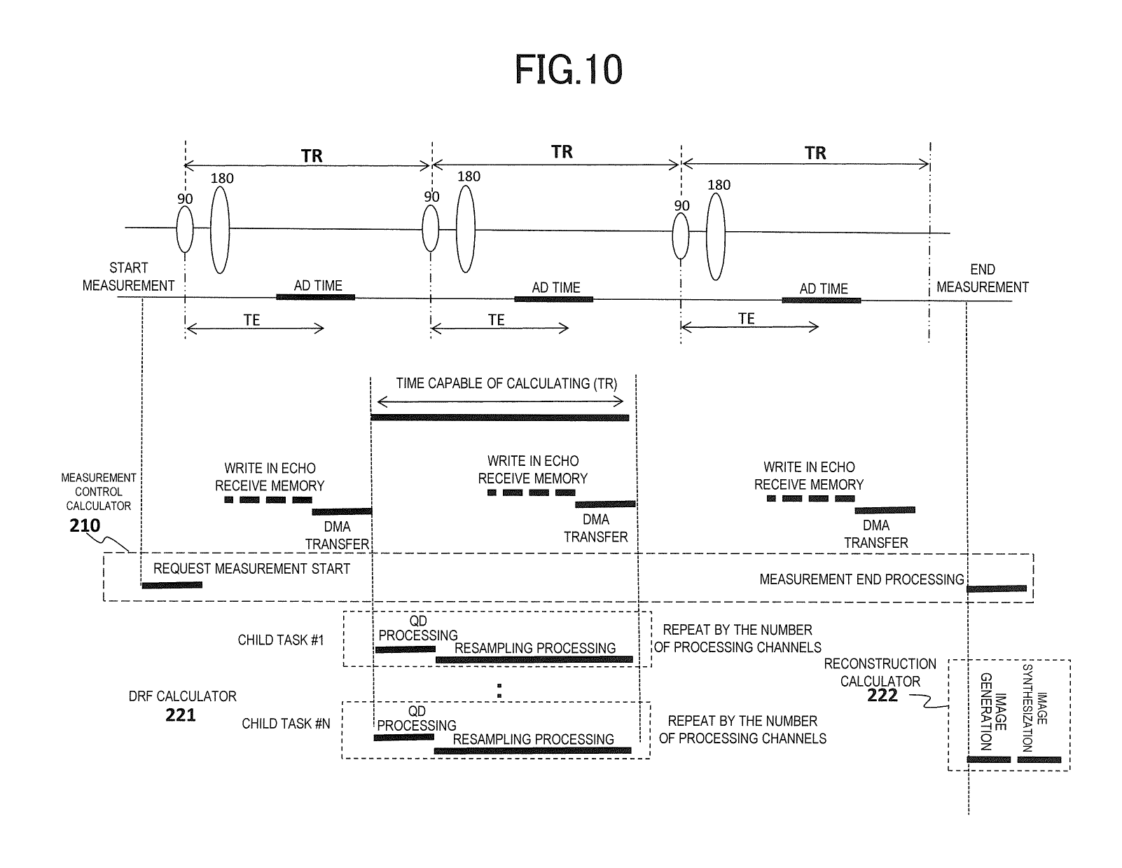

FIG. 10 is a time chart for processing echo signals from a plurality of channels within one calculation time (TR) of the first embodiment. As described above, in the present embodiment, the echo signal processes are performed in parallel by the child tasks by the number of logic cores. Also, DMA transfer is performed from the echo receive memory 243 to the main memory 244. Therefore, the logic cores of the CPU 245 in each of the DRF calculators 221 perform QD processing and resampling processing by the number of channels assigned to each child task. Furthermore, because the echo receive memory 243 is a two-sided bank-type memory, receive processing and acquiring processing of the echo signals can be performed simultaneously.

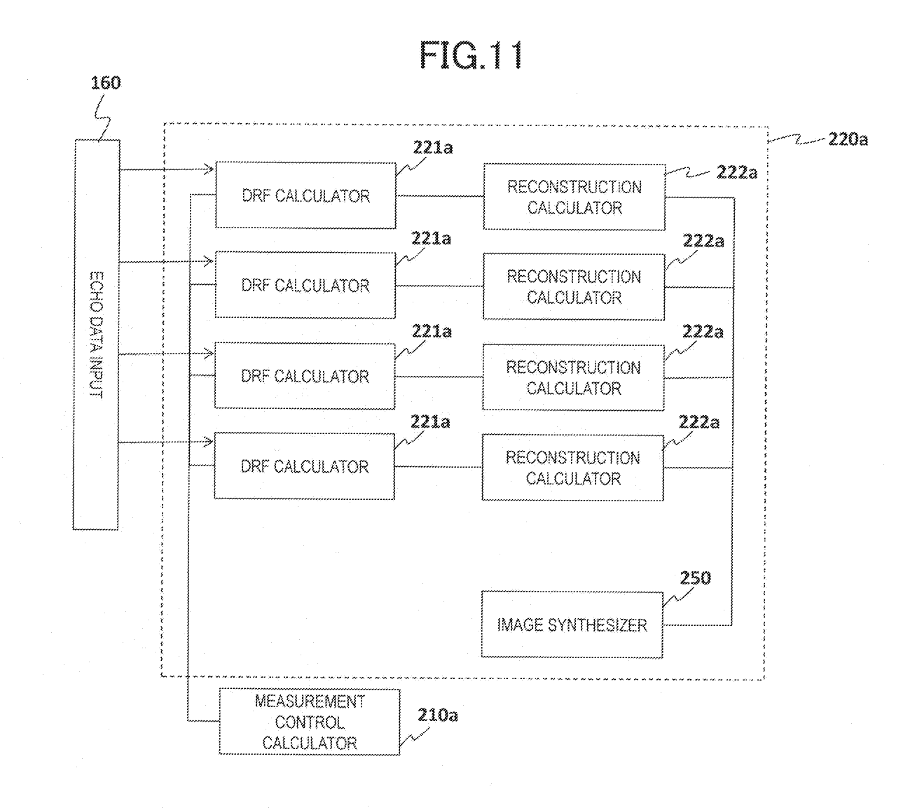

FIG. 11 shows a conventional image processing device 220a that was used for the comparison. As shown in the present drawing, signal processing devices (DRF calculators) 221a and image reconstruction devices (reconstruction calculators) 222a are connected in a lattice shape in the conventional image processing device 220a.

The DRF calculator 221a is provided with an interface for receiving echo signals of one channel. Therefore, the DRF calculators 221a are required by the number of channels.

As shown in the present drawing, data of each channel processed by each of the DRF calculators 221a is transferred to each of the reconstruction calculators 222a via a dedicated communication bus. Then, the data is converted into image data by performing a two-dimensional Fourier transform in each of the reconstruction calculators 222a. The image data of all the channels that was processed in the reconstruction calculators 222a is collected in an image synthesizer 250 where image synthesizing processing is executed to output a final image. Additionally, inputting echo signals to the DRF calculators 221a is controlled by the measurement control calculator 210a.

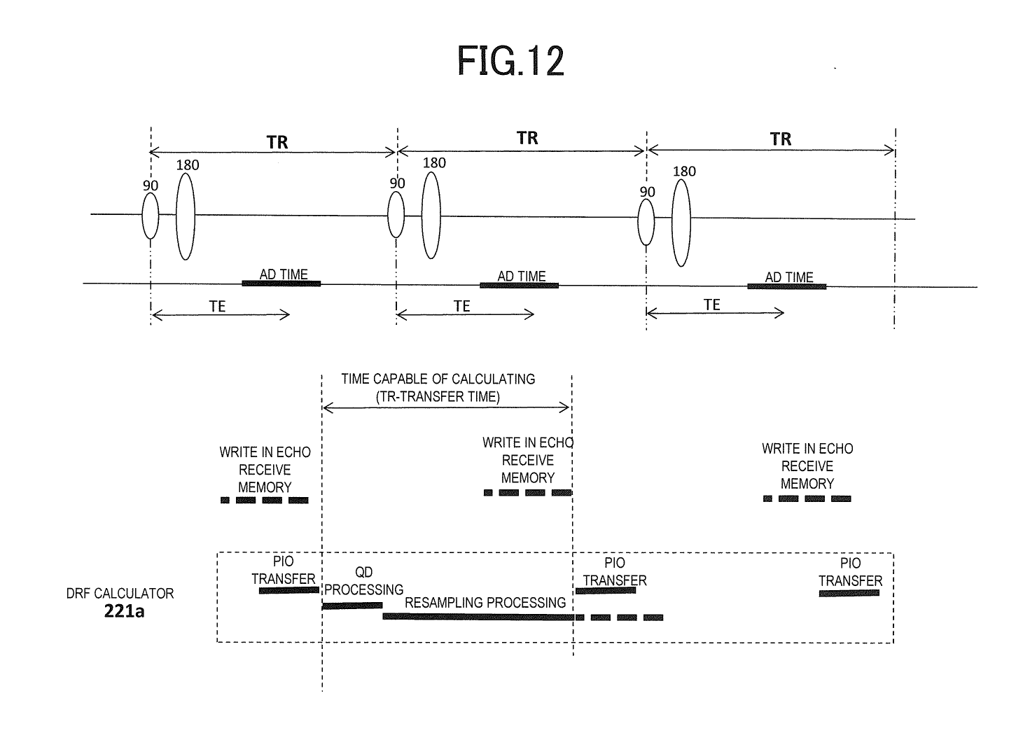

FIG. 12 is a time chart for processing echo signals from a plurality of channels within one TR by the conventional device. In the present embodiment, a CPU of each of the DRF calculators 221a performs QD processing and resampling processing for echo signals from one channel. However, the PIO (Programmed I/O) method is generally used for transferring between the internal memories. Therefore, the CPU load is high.

The conventional DRF calculators 221a receive echo signals of one channel and perform QD processing and resampling processing for the signals. For example, when various correction processes are performed for the received echo signals before the resampling processing in order to improve image quality, there is a possibility that the time to process all the signals exceeds a repetition time (TR). That is, it is difficult to add a correction process and the like to be performed for one echo signal before resampling and end the resampling processing starting from the echo signal reception within the TR.

The DRF calculators 221 can process multi-channel data in parallel at a high speed by CPU load reduction by the table generation of the FIR filter association and the DMA transfer of echo signals. Therefore, even if a correction process for the echo signals is added, calculation processing can be completed within a requested time.

Also, data of a plurality of channels is calculated in parallel within one of the DRF calculators 221 while the parent and child tasks are being synchronized. Hence, data of all the channels to be processed by one of the DRF calculators 221 can be transferred to the reconstruction calculator 222 all at once. Therefore, overhead due to the transfer can be reduced to the minimum.

As described above, the MRI apparatus 100 of the present embodiment comprises a receive coil 161 having a plurality of channels; and an image processing device 220 that processes signals received by the receive coil 161 to obtain an image, the image processing device 220 comprises one or more signal processing devices 221; one switching device 223; and an image reconstruction device 222 to be connected to each of the one or more signal processing devices 221 via the one switching device 223, each of the signal processing devices 221 comprises a multi-core CPU 245 provided with a plurality of logic cores; performs signal processes in parallel for signals received with two or more previously assigned channels from among the plurality of channels by the said multi-core CPU 245; and generates processed data for each channel, and the image reconstruction device 222 reconstructs an image from the processed data for each channel.

At this time, each of the signal processing devices 221 comprises a task generation function, the task generation function generates one parent task and a plurality of child tasks to be simultaneously executed under the said parent task, and each of the child tasks may be assigned to one logic core to perform the signal processing.

Thus, the MRI apparatus of the present embodiment is provided with a hardware comprising a receive interface 241 that can receive echo signals of a plurality of channels and multi-core CPUs that can perform DMA transfer between the internal memories. For echo signals of a plurality of channels, channel signal processing by the number of logic cores is performed while calculation tasks to be performed by the number of logic cores and a management task managing the calculation tasks are being synchronized. In order to perform the signal processing at a high speed, FIR filters with phases optimal for each sampling point are associated with data starting points in echo signals to which the filters are applied on tables generated by the number of frequency directions in advance before starting measurement.

As described above, processing channels are almost equally distributed to each of the one or more signal processing devices 221 according to the number of channels of the receive coil 161 in the present embodiment. Furthermore, the distributed processing channels are almost equally distributed to each CPU core also inside each of the signal processing devices 221. Therefore, processing loads are spread between the CPU cores and between the signal processing devices 221.

Also, according to the present embodiment, echo signal data of a plurality of channels temporally stored in the echo receive memory 243 is DMA-transferred to the main memory 244 for calculation inside each of the signal processing devices 221. Therefore, the load of the CPU 245 inside the signal processing device 221 is further reduced.

According to the MRI apparatus of the present embodiment, compared to the conventional method, a CPU load is reduced in each of the signal processing devices 221, which reduces the processing time. Therefore, this increases a possibility that calculation processing for each echo signal in the DRF calculators 221 is performed within TR. Hence, unless processing delay or the like does not occur in the reconstruction calculator 222, reconstruction time extension can be reduced.

Also, in the DRF calculators 221, multi-channel data can be stably processed in parallel at a high speed by proceeding the processing while synchronizing the parent and child tasks with each other. In addition to the synchronization processing, because each of the DRF calculators 221 and the reconstruction calculator 222 are connected in a star-shaped topology, data of all the channels processed by each of the DRF calculators 221 can be transferred to the reconstruction calculator 222 all at once, which can reduce overhead due to the transfer to the minimum.

The present embodiment has hardware and software configurations that can process each echo signal received by a plurality of channels in parallel. Also, the configuration elements are connected in a star-shaped topology. Therefore, in an MRI apparatus comprising a multi-channel receive coil, signal processing can be performed for data received by each channel at a high speed, and overhead due to transfer can be reduced, which can shorten the time to reconstruction.

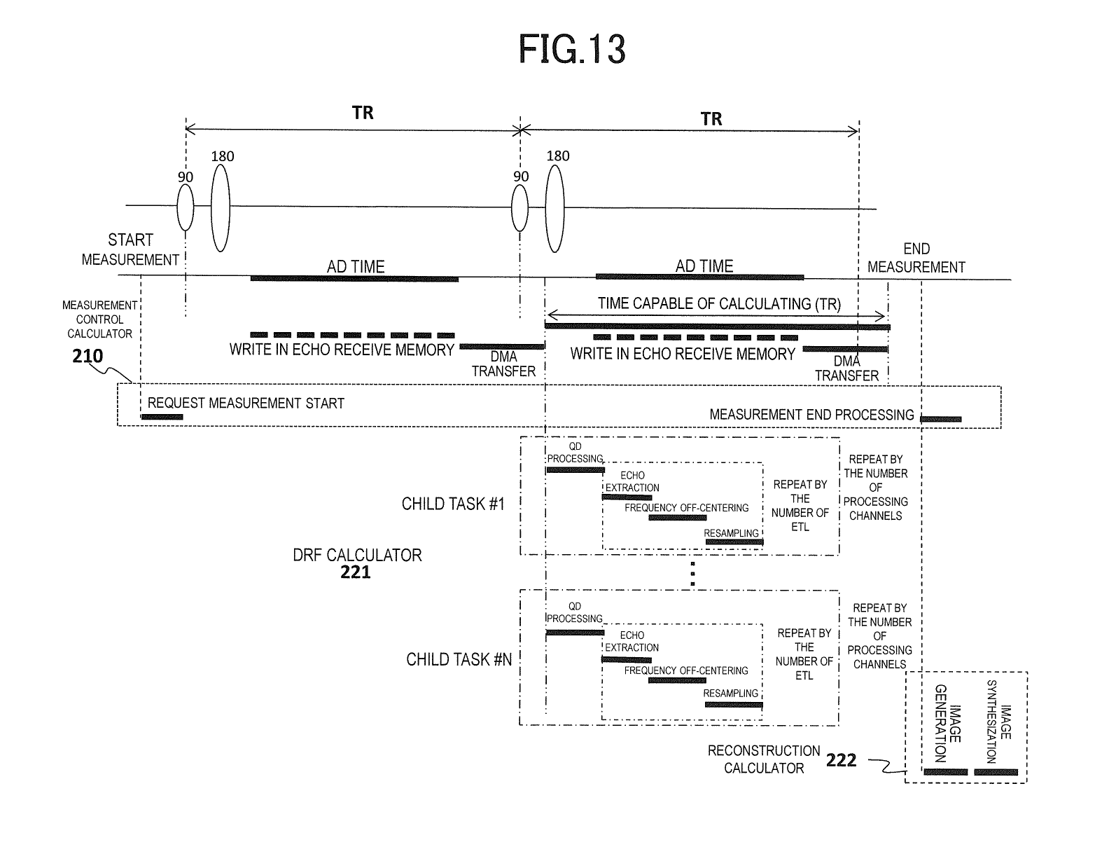

Additionally, in the present embodiment, a sequence for acquiring one echo signal for each AD was described as an example. However, as shown in FIG. 13, the present embodiment can be applied also to a sequence for collecting a plurality of echoes for each AD, for example, such as an EPI sequence.

In case of the EPI sequence, off-center processing in the frequency direction needs to be performed before echo extraction processing and resampling processing. Therefore, a calculation processing amount increases compared to a non-EPI sequence. However, according to the present embodiment, a CPU load is reduced, and calculation processing can be completed within a requested time.

### Second Embodiment

Next, a second embodiment of the present invention will be described. In the present embodiment executes a sequence for acquiring navigator echoes that detect displacement of a detection target site prior to an image acquisition sequence.

The MRI apparatus of the present embodiment is basically configured similarly to the MRI apparatus 100 of the first embodiment. The functional configuration of the control processing system 170 is also similar. Additionally, each device processing is also similar to the first embodiment. However, the contents of processing parent and child tasks differ in the present embodiment when navigator echoes are acquired. The processing when echo signals are acquired in the image acquisition sequence is similar to the first embodiment. Hereinafter, the present embodiment will be described by focusing on processes different from the first embodiment.

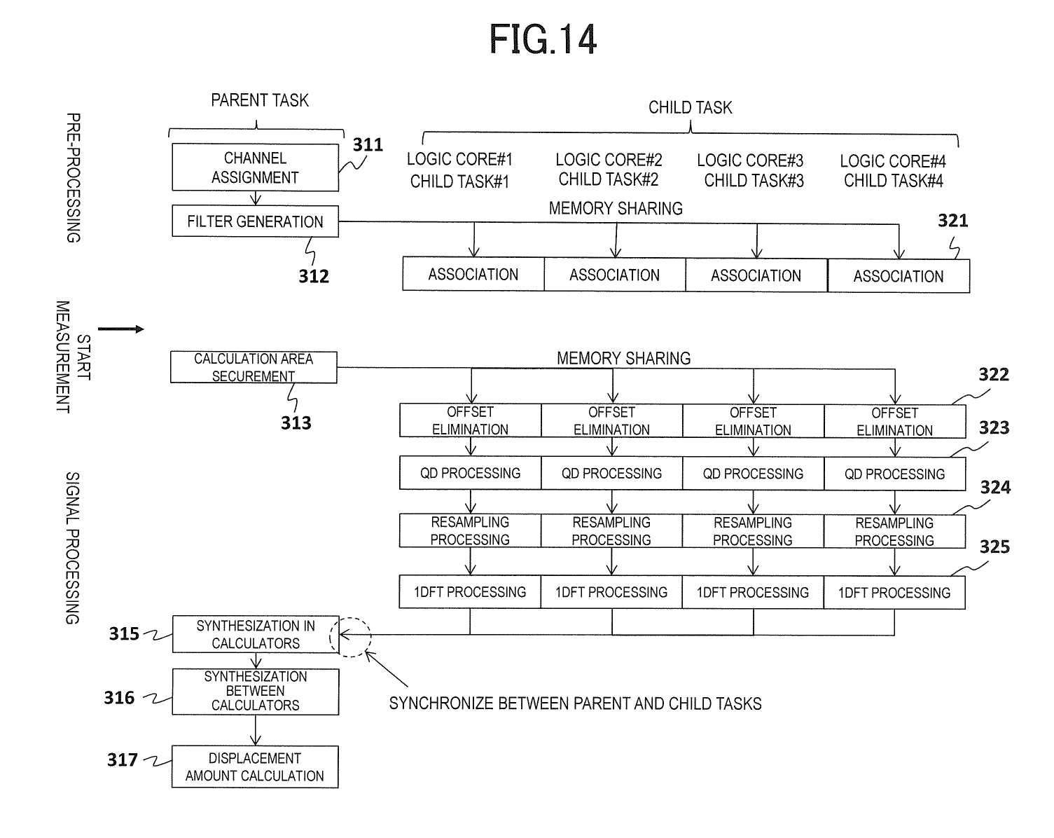

FIG. 14 shows an overview of processing in one DRF calculator 221 in the present embodiment when navigator echoes are acquired. As shown in the present drawing, pre-processing of both the parent and child tasks is the same as the normal echo signal acquisition described in the first embodiment.

However, each processing during measurement differs. In case of acquiring the navigator echoes, each child task performs processes up to a one-dimensional Fourier transform (1DFT processing 325). Also, when the child tasks end processing for all the channels, the parent task synthesizes (synthesization in calculators 315) the 1DFT results (processed navigation data) of all the channels in each of the DRF calculators 221. Then, the synthesized processed navigation data (synthesized data in the calculators) is collected in one predetermined DRF calculator 221, and the synthesized data in the calculators of all the DRF calculators 221 is synthesized (synthesization between calculators 316) in the said DRF calculator 221. Using the synthesization results, a displacement amount of a navigation data detection target site (detection point) is calculated (displacement amount calculation 317).

That is, in the present embodiment, the parent task does not transfer the processed navigation data of each child task stored in a shared memory to the reconstruction calculator 222 at a timing when synthesized with the child tasks. Instead of this, processes such as synthesization, displacement amount calculation, and determination are executed using the processed data.

Data for which a Fourier transform was performed (processed navigation data) of all the channels is converted into a data type of absolute values by the parent task in each of the DRF calculators 221, and then data is added to each other of each channel in order to form data in which channels were synthesized (synthesized data in the calculators).

In one DRF calculator 221 in which the synthesized data in all the calculators was collected, the parent task adds the synthesized data in the calculators acquired from each calculator to each other in order to generate final synthesized data (synthesized data between the calculators). Additionally, the DRF calculator 221 that collects and generates the synthesized data in the calculators is determined in advance. Hereinafter, the DRF calculator 221 that collects the synthesized data in the calculators and generates the synthesized data between the calculators is referred to as a main DRF calculator 221.

The parent task of the main DRF calculator 221 is correlated with a reference echo obtained in advance using the synthesized data between the calculators to calculate a shift amount (displacement amount) from the reference. Then, based on the shift amount, a detection point of navigation data may be calculated. Also, based on the displacement amount, subsequent adoption or rejection of echo signals may be determined.

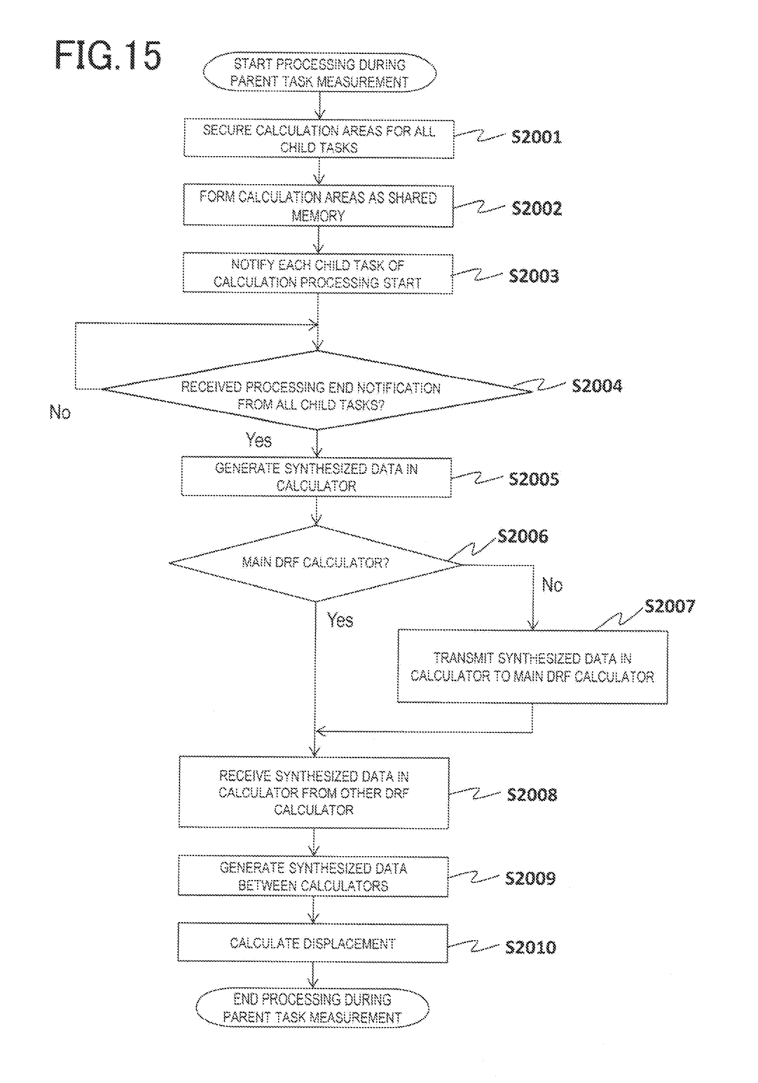

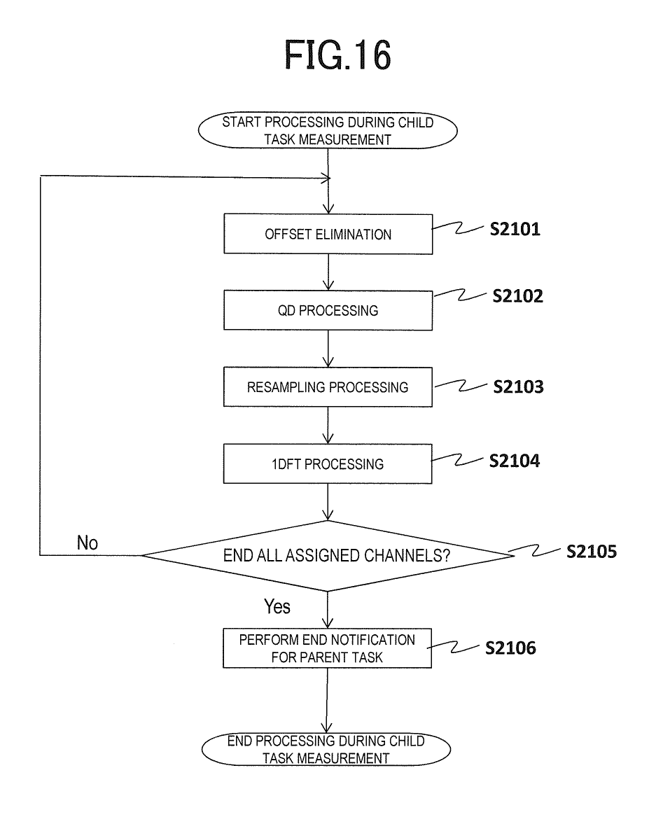

Hereinafter, described is a flow of processing during measurement while the parent and child tasks of the present embodiment are measuring navigator echoes. FIGS. 15 and 16 show processing flows of the parent task and the child tasks respectively.

Also in the present embodiment, similarly to the first embodiment, a DMA controller performs DMA transfer from the echo receive memory 243 to the main memory 244 by the number of reception channels, and the parent task starts processing while navigator echoes are being measured after the present processing ends.

The parent task secures calculation areas of all the child tasks (Step S2001). Then, the secured calculation areas are formed as a shared memory (Step S2002). Also in the present embodiment, navigator echo signals DMA-transferred to the main memory 244 are formed as a shared memory after the parent task secures the calculation areas of all the child tasks. Then, a command to start child task processing during measurement is transmitted to each child task (Step S2003). Lastly, the parent task waits for end notifications from the child tasks.

The parent task receives processing end notifications from each child task (Step S2004) and synthesizes processed navigation data in the said DRF calculator 221 to generate synthesized data in the calculator (Step S2005).

Then, the DRF calculator determines whether or not to be the main DRF calculator 221 (Step S2006). When the parent task is not the main DRF calculator 221, the synthesized data in the calculator is transmitted to the main DRF calculator 221 (Step S2007).

On the other hand, when the DRF calculator is the main DRF calculator 221, the synthesized data in the calculator is received from the other DRF calculators 221 (Step S2008). Then, including the synthesized data in the calculator of the parent task, the parent task synthesizes all the synthesized data in the calculators to generate the synthesized data between the calculators (Step S2009). Lastly, using the generated synthesized data between the calculators, a displacement amount of a detection target site (detection point) is calculated (Step S2010), and then the processing ends. Additionally, when a determination was made in Step S2010, the determination results are used for adoption or rejection of echo data acquired in an image acquisition sequence to be executed later.

Next, according to FIG. 16, described is a flow of processing during measurement by the child tasks that is performed after a start notification is received from the parent task.

The child tasks first perform an offset removing process for echo signals from a first channel (Step S2101). Then, QD processing is performed by referring to a QD table (Step S2102), and resampling processing is performed using FIR filters according to the association (Step S2103). Lastly, a one-dimensional Fourier transform (1DFT processing) is performed (Step S2104) to acquire processed navigation data. The acquired processed navigation data is stored in a shared memory area.

The child tasks perform processes from Steps S2101 to S2104 for all the echo signals of all the assigned channels (Step S2105). Then, when the processes for all the echo signals of all the channels end, a processing end notification is transmitted to the parent task (Step S2106), and the processing ends.

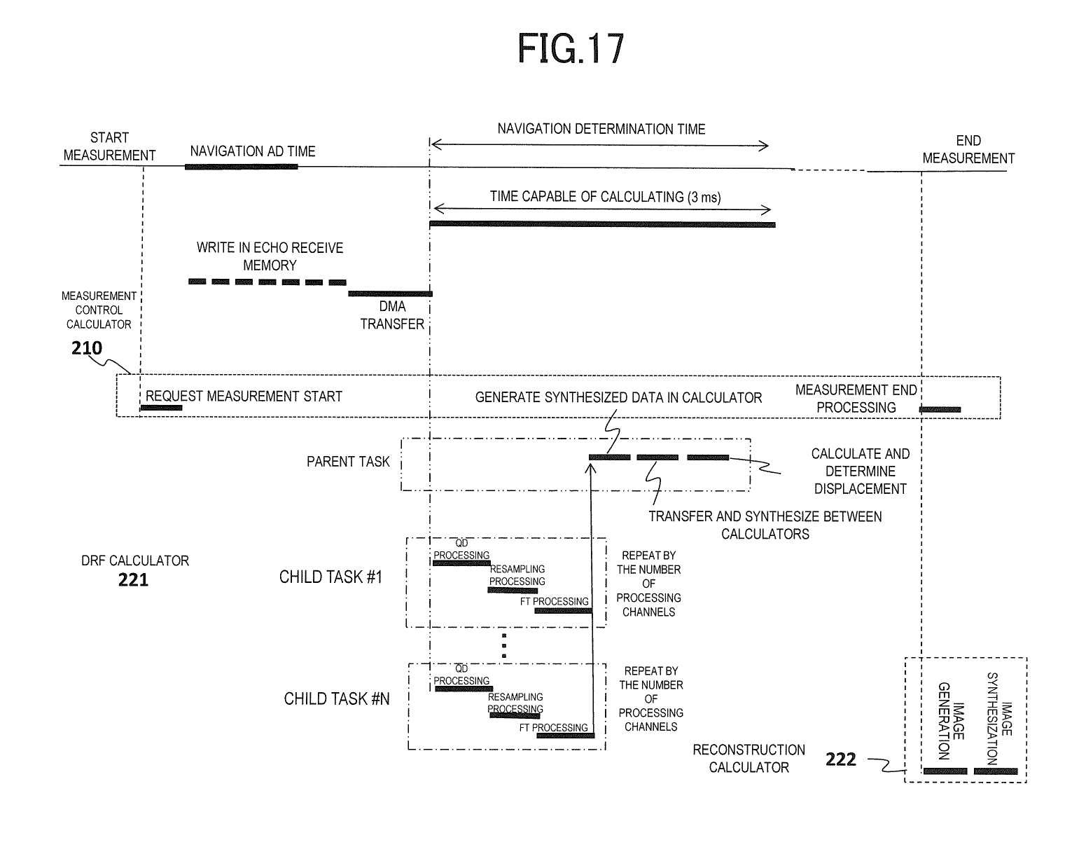

FIG. 17 is a time chart for signal processing when navigator echoes of the present embodiment are acquired. As describe above, echo signal processes are performed in parallel by the child tasks by the number of logic cores. At this time, when the navigator echoes are processed, the processes up to a one-dimensional Fourier transform are performed by each child task. Then, data of each channel after the Fourier transform is synthesized by the parent task, the processes up to the calculation and determination of displacement are performed.

As described above, the MRI apparatus 100 of the present embodiment comprises a receive coil 161 and an image processing device 220 similarly to the first embodiment, the image processing device 220 comprises one or more signal processing devices 221; one switching device 223; and an image reconstruction device 222, and each of the signal processing devices 221 comprises a multi-core CPU 245. Then, each of the signal processing devices 221 comprises a task generation function, the task generation function generates one parent task and a plurality of child tasks to be simultaneously executed under the said parent task, and each of the child tasks may be assigned to the one logic core to perform the signal processing.

Furthermore, in the MRI apparatus 100 of the present embodiment, when signals received by the receive coil 161 are navigator echoes to detect displacement of a detection target site, the signal processing devices 221 may calculate displacement of the detection target site using the navigator echoes.

Thus, according to the present embodiment, high-speed signal processing can be performed for data received by each channel in order to shorten time required to calculate a detection point by navigator echoes similarly to the first embodiment in an MRI apparatus comprising a multi-channel receive coil.

In the present embodiment, in order to calculate a detection point of navigation data, synthesized data in the calculators of all the DRF calculators 221 is collected in the predetermined main DRF calculator 221 to generate final synthesized data. In a conventional system comprising a number of the DRF calculators 221, a large amount of transfer data concentrates on communication buses connecting between the calculators, and it takes a long time to perform transmission between the calculators.

However, according to the present embodiment, first, the number of the DRF calculators 221 in the system becomes one the number of channels by using the DRF calculators 221 that can receive data of a plurality of channels. Hence, a rate of data transfer between the calculators to a calculation processing time of one navigator echo is reduced. Furthermore, inside each of the DRF calculators 221, multi-core CPUs are provided to process navigator echoes of each channel in parallel. Additionally, by comprising a DMA controller, there is little difference compared to the time to process one echo signal even in the parallel processing.

The second embodiment of the present invention was described as above. In the present embodiment, compared to conventional embodiments, shortening an imaging time in the entire navigation sequence can be achieved by considerably reducing a processing time from AD of navigator echoes to detection point calculation.

<Variation 1>

Additionally, in each of the above embodiments, the measurement control device 210 may comprise a function of switching transmission paths for inputting echo signals to each of the DRF calculators 221 from each channel of the receive coil 161.

The number of the DRF calculators 221 is determined in consideration with a maximum value of the number of channels of the receive coil 161 due to the system configuration. That is, the DRF calculators 221 can be provided by the maximum number of channels that can be processed. For example, in a case where the DRF calculators 221 are configured so that echo signals of eight channels can be input and the maximum number of channels of the receive coil 161 is 32 channels, four of the DRF calculators 221 are provided.

However, there is a case of using a receive coil having the number of channels equal to or less than the maximum number of channels that can be processed for imaging. In such a case, the measurement control device 210 exclusively assigns transmission paths from each channel to be actually used to each of the DRF calculators 221 in order to enable using existing components maximally effectively. In this case, each channel is almost equally assigned to each of the DRF calculators 221.

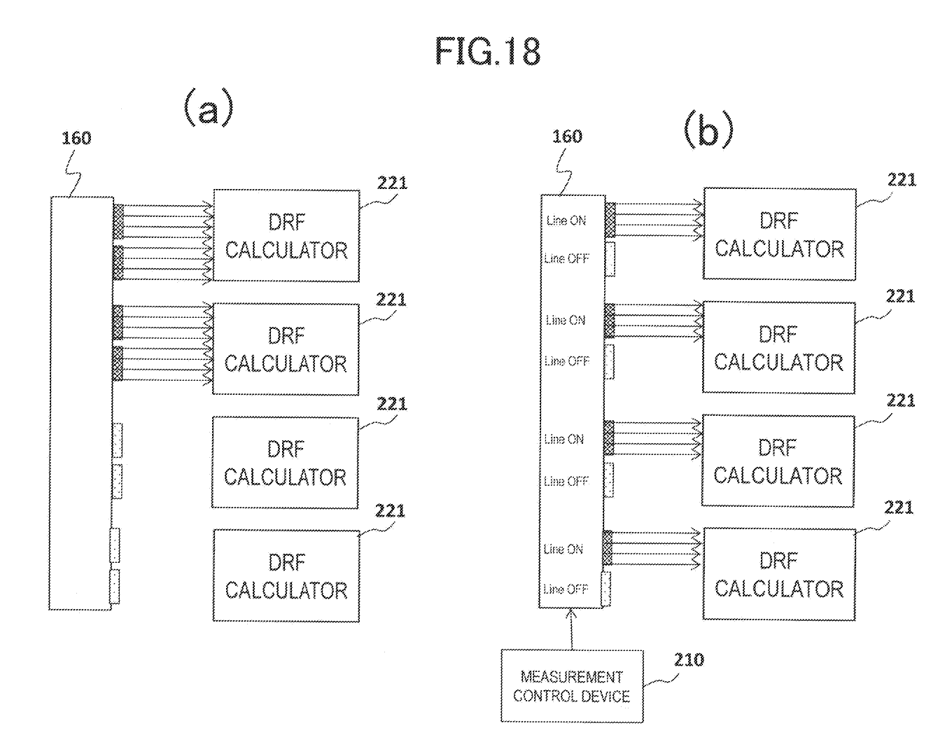

FIGS. 18(a) and 18(b) show modes to input echo signals to each of the DRF calculators 221 in a case of comprising the function and in a case of not comprising the function respectively. Shown here is the case of comprising four of the DRF calculators 221 that can accept eight channels as an example. In this case, 32 channels can be processed at maximum.

As shown in FIG. 18(a), in a case of not comprising the present function and using 16 channels only, eight channels of transmission paths are set respectively for two of the predetermined DRF calculators 221.

On the other hand, in a case of comprising the present function, the measurement control device 210 sets transmission paths from the reception system 160 so that processes in each of the DRF calculators 221 are almost equal. In the present example, four transmission paths are assigned respectively to four of the DRF calculators 221 as shown in FIG. 18(b).

Specifically, after determining a receive coil to be used and the number of channels, the measurement control device 210 switches the transmission paths for inputting echo signals to the DRF calculators 221 from the reception system 160.

In each of the DRF calculators 221, signal processes are performed in parallel for the input echo signals using multi-core CPUs in the DRF calculators 221 similarly to the first embodiment. At this time, because the number of echo signals to be input all at once is reduced, the number of processing channels to be assigned to each child task is reduced.

Thus, when the measurement control device 210 comprises a function of almost equally assigning a plurality of channels to be actually used to each of the DRF calculators 221, an amount of data to be processed in one DRF calculator 221 can be reduced by switching paths for inputting echo signals to the DRF calculators 221 from the reception system 160 in advance in a case where the number of channels to be actually used is less than a maximum number of channels that can be systematically processed. Hence, signal processing calculation can be performed in each of the DRF calculators 221 at a higher speed. Consequently, the time to image reconstruction can be shortened. Thus, system resources can be utilized efficiently according to the number of reception channels.

<Variation 2>

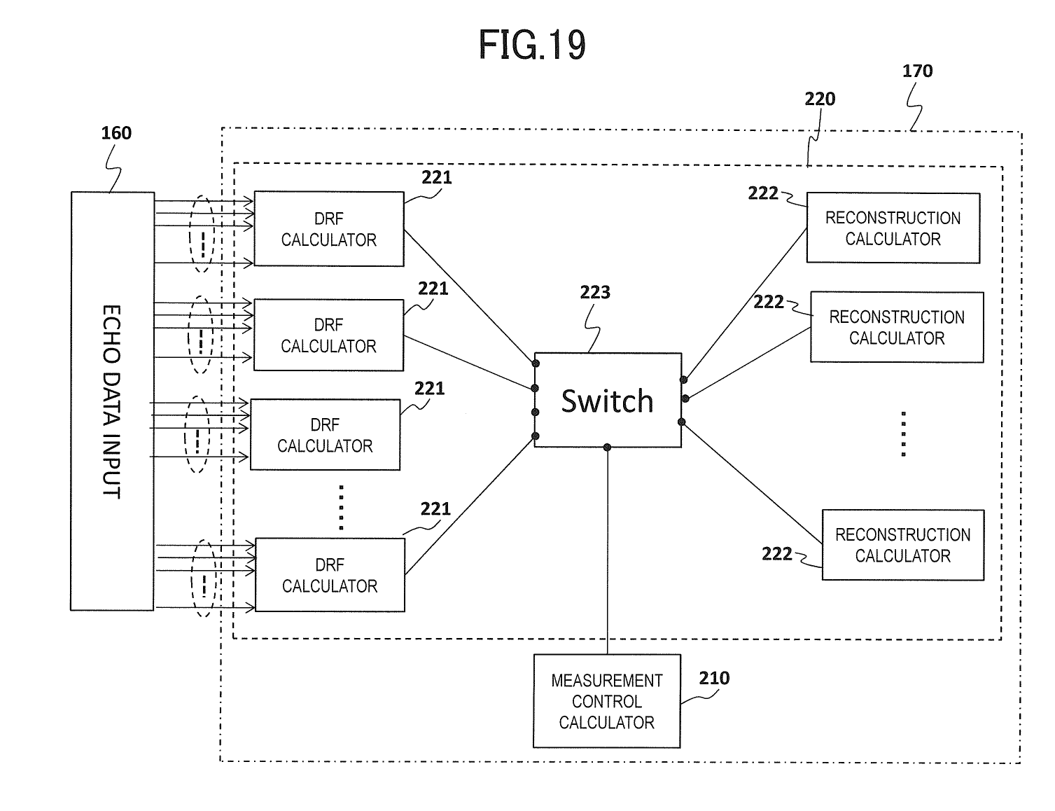

Also, in each embodiment, a plurality of the reconstruction calculators 222 may be provided in order to reconstruct an image from data processed by the DRF calculators 221. FIG. 19 shows a configuration and an inside connection mode of the image processing device 220 for this case.

As shown in the present drawing, each of the DRF calculators 221, each of the reconstruction calculators 222, and the measurement control calculator 210 are connected via one switching device 223 in a star-shaped topology. A switching hub or the like is used for the switching device 223.

In this case, there are a plurality of the reconstruction calculators 222, and information is required about to which reconstruction calculator 222 echo signals are transmitted from DRF circuit boards. This is determined by the measurement control calculator 210. That is, the measurement control calculator 210 previously determines to which reconstruction calculator 222 each of the DRF calculators 221 transmits processed data of each channel. The determination is made so that processing loads of the respective reconstruction calculators 222 are almost even. Furthermore, a transmission destination of the processed data is determined for each of the DRF calculators 221.

A parent task of each of the DRF calculators 221 transmits processed data to a reconstruction calculator 222 that is a predetermined transmission destination. The transmission is performed by providing the transmission destination information to a header. The parent task obtains the transmission destination information of echo signals from the measurement control calculator 210 in pre-processing. Then, calculation processes are performed in parallel for input echo signals using multi-core CPUs in the DRF calculators 221. After this, the processed data of the number of channels processed by the DRF calculators 221 of the parent task is transmitted to the reconstruction calculators 222 specified for each of the said DRF calculators 221.

The two processes to be performed by the reconstruction calculators 222 are reconstructing images of the number of channels and synthesizing the reconstruction images. In this case, reconstructing an image for each channel is performed in each of the previously assigned reconstruction calculators 222. The reconstruction image for each channel is stored in a shared area of a predetermined memory. Then, all the reconstruction images are synthesized in one predetermined reconstruction calculator 222.

Processing loads and a memory use amount of the processes of the reconstruction calculators 222 are increased depending on the number of channels, the number of images, the reconstruction matrix size, and the like. However, reconstruction processing loads are spread to shorten the entire reconstruction time by being provided with the two or more reconstruction calculators 222 and by that the measurement control calculator 210 determines a reconstruction calculator 222 processing processed data in each of the DRF calculators 221 so that the processing loads of the respective reconstruction calculators 222 are almost even. This can increase the number of images capable of being imaged at a high resolution.

Additionally, a processing load is increased for a reconstruction calculator 222 that performs image synthesization compared to the other reconstruction calculators 222 that performs image generation only. Therefore, such a reconstruction calculator 222 may be configured so as to reduce the number of processing channels for the image generation when the channels are assigned by the measurement control calculator 210. This can spread loads more evenly, which can further reduce a processing load on each of the reconstruction calculators 222 as a whole.

### REFERENCE SIGNS LIST

100: MRI apparatus
101: object
120: static magnetic field generating system
130: gradient magnetic field generating system
131: gradient magnetic field coils
132: gradient magnetic field power sources
140: sequencer
150: transmission system
151: transmission coil
152: high-frequency oscillator
153: modulator
154: high-frequency amplifier
160: reception system
161: receive coil
162: signal amplifier
163: quadrature phase detector
164: A/D converter
170: control processing system
172: storage device
173: display device
174: input device
210: measurement control device (measurement control calculator)
210a: measurement control device (measurement control calculator)
220: image processing device
220a: image processing device
221: signal processing devices (DRF calculators)
221a: signal processing devices (DRF calculators)
222: image reconstruction devices (reconstruction calculators)
222a: image reconstruction devices (reconstruction calculators)
223: switching device
241: receive interface
243: echo receive memory
244: main memory
245: CPU
250: image synthesizer
311: channel assignment
312: filter generation
313: calculation area securement
314: data transmission
315: synthesization in calculators
316: synthesization between calculators
317: displacement amount calculation and determination
321: FIR filter association
322: offset removal
323: QD processing
324: resampling processing
325: 1DFT processing
400: table
401: number of applications
402: data starting point address
403: filters with the optimal phases
404: offsets

1. A magnetic resonance imaging apparatus comprising:
a receive coil that has a plurality of channels; and
an image processing device that processes signals received by the receive coil to obtain an image,
wherein the image processing device comprises:
one or more signal processing devices;
one switching device; and
an image reconstruction device that is connected to each of the one or more signal processing devices via the one switching device,
each of the signal processing devices comprises a multi-core CPU provided with a plurality of logic cores; performs signal processes in parallel for signals received with two or more previously assigned channels from among the plurality of channels by the said multi-core CPU; and generates processed data for each channel, and
the image reconstruction device reconstructs an image from the processed data for each of the channels.

2. The magnetic resonance imaging apparatus according to claim 1,
wherein each of the one or more signal processing devices comprises a task generation function,
the task generation function generates one parent task and a plurality of child tasks to be simultaneously executed under the said parent task, and
each of the child tasks is assigned to the one logic core to perform the signal processing.

3. The magnetic resonance imaging apparatus according to claim 2,
wherein the parent task and each of the child tasks perform pre-processing for generating data to be used for the signal processing prior to the said signal processing.

4. The magnetic resonance imaging apparatus according to claim 3,
wherein the signal processing includes resampling processing that thins out the signals,
the parent task generates a plurality of filters to be used for the resampling processing as data to be used for the signal processing in the pre-processing, and
each of the child tasks determines filters whose phases correspond to each other from among the plurality of generated filters for each sampling point to be used for the resampling processing as data to be used for the signal processing in the pre-processing to generate a table in which the said sampling point corresponds to the said filters.

5. The magnetic resonance imaging apparatus according to claim 2,
wherein the signals received by the receive coil are navigator echoes to detect displacement of a detection target site, and
the signal processing devices calculate the displacement of the detection target site using the navigator echoes.

6. The magnetic resonance imaging apparatus according to claim 2,
wherein, when the number of channels to be assigned to the one signal processing device is equal to or more than the number of logic cores of the said signal processing device, the task generation function generates the child tasks by the number of logic cores,
the parent task assigns the channels to each of the child tasks according to the predetermined assignment,
the child tasks perform the signal processing for signals acquired by the assigned channels to obtain the processed data, and
the parent task collectively transmits processed data of all the assigned channels to the image reconstruction device.

7. The magnetic resonance imaging apparatus according to claim 1,
wherein a measurement control device is further provided, and
the measurement control device almost equally assigns the plurality of channels to each of the signal processing devices.

8. The magnetic resonance imaging apparatus according to claim 1,
wherein a measurement control device is further provided,
the two or more image reconstruction devices are connected via the switching device, and
the measurement control device determines the image reconstruction device that processes each of the processed data so that processing loads of the respective image reconstruction devices are approximately equal.

9. The magnetic resonance imaging apparatus according to claim 1,
wherein each of the signal processing devices comprise:
a receive memory that temporally stores the received signals; and
a main memory that stores the received signals when the signal processing is performed, and
the received signals are DMA-transferred to the main memory from the receive memory.

10. The magnetic resonance imaging apparatus according to claim 9,
wherein the receive memory is a double-sided switching system memory that can store and read out the received signals in parallel.

11. The magnetic resonance imaging apparatus according to claim 1,
wherein each of the signal processing devices comprise a receive interface that can receive a plurality of signals in parallel.
